(19) United States
(12) Patent Application Publication
(10) Pub. No.: US 2016/0326648 A1
(43) Pub. Date: Nov. 10, 2016

(54) APPARATUS FOR SELECTIVELY SEALING A GAS FEEDTHROUGH

(71) Applicant: APPLIED MATERIALS, INC., Santa Clara, CA (US)

(72) Inventors: Hyman W. H. Lam, San Jose, CA (US); Dien-Yeh Wu, San Jose, CA (US); Paul F. Ma, Santa Clara, CA (US); Daping Yao, San Jose, CA (US)

(21) Appl. No.: 15/148,158

(22) Filed: May 6, 2016

Related U.S. Application Data
(60) Provisional application No. 62/158,520, filed on May 7, 2015.

(51) Int. Cl. C23C 16/455; F16K 25/00; C23C 16/52

(52) U.S. Cl. CPC C23C 16/45589; C23C 16/45565; C23C 16/52; F16K 25/00

(57) ABSTRACT

A valve for sealing a gas feedthrough is provided herein. In some embodiments, a valve for sealing off a gas feedthrough includes a valve body having an upper portion and a lower portion, wherein the upper portion includes a central opening, and wherein the lower portion includes an inner volume; a coupling member disposed within the inner volume and having a central conduit, wherein the inner volume is defined by an upper surface of the coupling member and an upper wall and sidewalls of the lower portion; a sealing member having a shaft extending through the central opening and a flange extending radially outward from the shaft, wherein the flange includes an upper surface which opposes the upper wall of the lower portion; and a biasing element disposed between the sealing member and coupling member to bias the sealing member against the upper wall.

### CROSS-REFERENCE TO RELATED APPLICATIONS

This application claims benefit of U.S. provisional patent application Ser. No. 62/158,520, filed May 7, 2015, which is herein incorporated by reference.

### FIELD

Embodiments of the disclosure generally relate to method and apparatus for processing a substrate.

### BACKGROUND

Processing chambers are cleaned between processes to ensure optimal processing results. During cleaning, a lid of a processing chamber is open, thus leaving a gas feedthrough exposed to ambient air, which causes particle generation due to deposition of process precursor on walls of the gas feedthrough. Presently, when the lid is opened for cleaning of the process chamber, a purge gas is flowed through the gas feedthrough to prevent the feedthrough from being exposed to the ambient air. However, flowing the purge gas through the feedthrough may result in process precursor flowing out to the surrounding environment.

Therefore, the inventors have provided an improved valve for sealing a gas feedthrough.

### SUMMARY

Valves for sealing a gas feedthrough are provided herein. In some embodiments, a valve for sealing off a gas feedthrough including a valve body having an upper portion and a lower portion, wherein the upper portion includes a central opening and is configured to interface with a gas line, and wherein the lower portion includes an inner volume; a coupling member disposed within the inner volume and having a central conduit configured to be coupled to the gas feedthrough, wherein the inner volume is defined by an upper surface of the coupling member and an upper wall and sidewalls of the lower portion; a sealing member having a shaft extending through the central opening and a flange extending radially outward from the shaft in the inner volume, wherein the flange includes an upper surface which opposes the upper wall of the lower portion; and a biasing element disposed between the sealing member and the coupling member to bias the sealing member against the upper wall to seal off the inner volume.

In some embodiments, a chamber body defining a processing region within; a lid pivotably coupled to the chamber body to close off the processing region; a gas feedthrough extending through the chamber body to provide a process gas to the lid, wherein the gas feedthrough includes a valve disposed at an interface between the gas feedthrough the lid, the valve comprising: a valve body having an upper portion and a lower portion, wherein the upper portion includes a central opening and is configured to interface with a gas line, and wherein the lower portion includes an inner volume; a coupling member disposed within the inner volume and having a central conduit configured to be coupled to the gas feedthrough, wherein the inner volume is defined by an upper surface of the coupling member and an upper wall and sidewalls of the lower portion; a sealing member having a shaft extending through the central opening and a flange extending radially outward from the shaft in the inner volume, wherein the flange includes an upper surface which opposes the upper wall of the lower portion; and a biasing element disposed between the sealing member and the coupling member to bias the sealing member against the upper wall to seal off the inner volume.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional view of a valve in accordance with some embodiments of the present disclosure.

FIG. 2 depicts a schematic cross-sectional view of a process chamber in accordance with some embodiments of the present disclosure.

FIG. 3 depicts a perspective view of a process chamber in accordance with some embodiments of the present disclosure.

FIG. 4 depicts a perspective view of a lid for a process chamber in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure generally relate to a valve for sealing a gas feedthrough. Embodiments of the inventive valve advantageously seal off a gas feedthrough when a lid of a process chamber is opened, thus sealing off the gas feedthrough from ambient air.

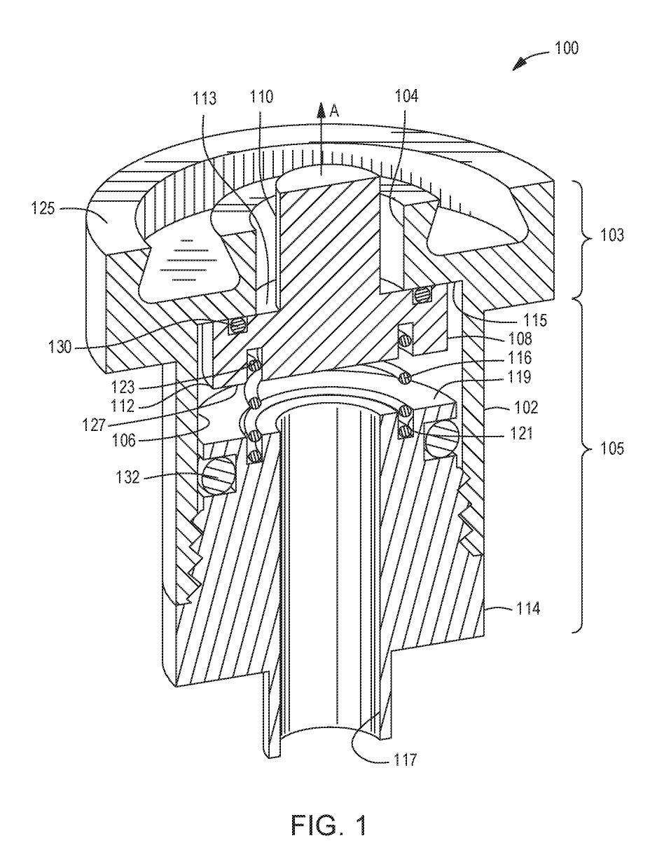

FIG. 1 depicts a valve 100 for sealing off a gas feedthrough in accordance with some embodiments of the present disclosure. In some embodiments, the valve 100 includes a valve body 102 having an upper portion 103 and a lower portion 105. The upper portion 103 includes a central opening 104 and is configured to interface with a gas line (not shown). The lower portion 105 includes an inner volume 106.

The valve 100 further includes a sealing member 108 having a shaft 110 extending through the central opening 104 and a flange 112 extending radially outward from the shaft 110 in the inner volume 106. The flange 112 includes an upper surface 113 which opposes an upper wall 115 of the lower portion 105. The sealing member 108 is moveable between a first position(shown in FIG. 1), in which the sealing member 108 seals off the inner volume 106, and a second position, in which the inner volume 106 is fluidly coupled to the central opening 104. In the first position, the upper surface 113 of the flange 112 abuts the upper wall 115 of the lower portion 105. In some embodiments, an o-ring 130 may be disposed in a groove formed in the upper surface 113 to improve the sealing off of the inner volume 106. In some embodiments, in the second position, a spacing between a lower surface 127 of the flange 112 and the upper surface 119 of coupling member 114 is about 5 millimeters. However, the spacing between a lower surface 127 and the upper surface 119 may be any spacing needed to achieve a desired flowrate between a gas source and the gas line (not shown) coupled to the upper portion. The sealing member 108 is formed of a material that can withstand temperatures of up to 150° C. In some embodiments, the sealing member 108 is formed of a polymer such as, for example, polytetrafluoroethylene or VESPEL®. In some embodiments, the sealing member 108 may be formed of aluminum.

The valve 100 further includes a coupling member 114 having a central conduit 117 that is configured coupled to a gas delivery line (i.e., a gas feedthrough) (not shown). The coupling member 114 is partially disposed within the inner volume 106, which is defined by an upper surface 119 of the coupling member 114 and the upper wall 115 and sidewalls of the lower portion 105. A lower portion of the central conduit 117 is coupled to the gas delivery line in a manner that ensures a proper seal at an interface between the central conduit 117 and the gas delivery line. In some embodiments, the central conduit 117 may be welded to the gas delivery line. In some embodiments, the coupling member 114 includes an o-ring 132 disposed in an annular groove formed in the coupling member 114 to ensure proper sealing of the inner volume 106.

A biasing element 116 is disposed between the flange 112 and the coupling member 114 to bias the sealing member 108 against the upper wall 115 to seal off the inner volume 106 (i.e., in a direction along arrow A). In some embodiments, the biasing element 116 may be a helical spring. However, the biasing element 116 may be any suitable element that provides the necessary biasing force to seal off the inner volume 106. In such an embodiment, a first annular groove 121 may be formed in the coupling member 114 and a second annular groove 123 may be formed in the sealing member 108 to rigidly hold the biasing element 116 rigidly in place.

In some embodiments, the shaft 110 protrudes beyond an upper surface 125 of the upper portion 103. For example, shaft 110 may protrude beyond the upper surface 125 by about 2.5 millimeters. The shaft 110 protrudes beyond the upper surface 125 so that a force provided to the shaft in a direction opposite arrow A that is greater than a biasing force of the biasing element 116 moves the sealing member 108 in a direction opposite arrow A.

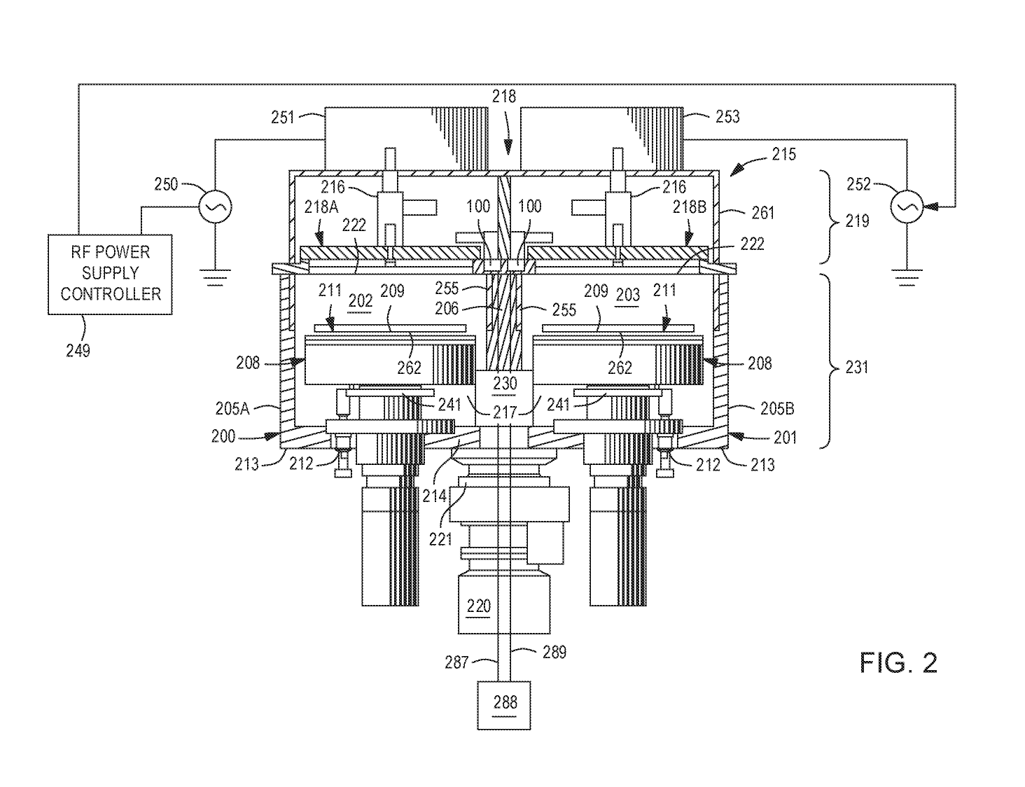

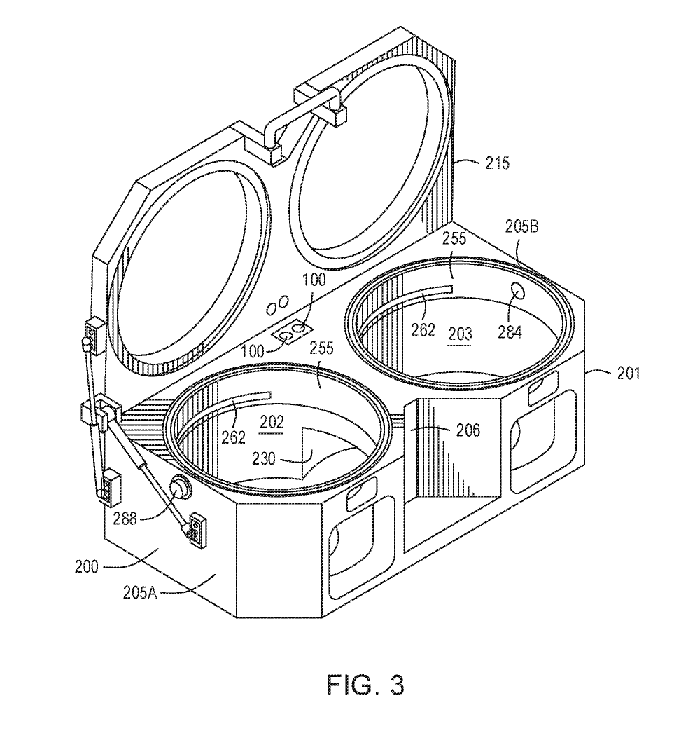

The following process chamber description is provided for context and exemplary purposes, and should not be interpreted or construed as limiting the scope of the disclosure. FIGS. 2 and 3 illustrate cross-sectional and perspective views, respectively, of an exemplary processing chamber (e.g., tandem process chambers 200, 201) in which the inventive valve 100 may be used in accordance with some embodiments of the present disclosure. Each of the respective first and second tandem process chambers 200, 201 may include an upper portion 219 and a lower portion 231, wherein the upper portion 219 generally includes processing regions 202, 203 and wherein the lower portion 231 generally includes a loading region 211 adjacent an aperture 209. Each of the respective first and second tandem process chambers 200, 201 include a chamber body having sidewalls 205A,B, an interior wall 206, a bottom 213, and a lid 215 disposed on the first and second tandem process chambers 200, 201. The sidewall 205A, interior wall 206, and portion of lid 215 disposed on the first tandem process chamber 200 define a first processing region 202. The sidewall 205B, interior wall 206 and portion of lid 215 disposed on the second tandem process chamber 201 define a second processing region 203. The interior wall 206 is shared between the respective first and second tandem process chambers 200, 201 and isolates the processing environment of the processing regions 202, 203 from each other. As such, the processing regions 202, 203 defined in the respective process chambers 200, 201 while process isolated, may share a common pressure, as the lower portion of interior wall 206 may allow the respective first and second tandem process chambers 200, 201 to communicate with each other. The lower portion of interior wall 206 is defined by a central pumping plenum 217 described below.

The lid 215 may include one configuration of a gas distribution assembly 216 including a showerhead 222 configured to dispense a gas from a gas source 288 into the respective processing regions 202, 203. The lid 215 is coupled to the gas source 288 via respective gas feedthroughs 287, 289 corresponding to processing regions 202, 203, respectively. The inventive valve 100 is coupled to an upper portion of each of the gas feedthroughs 287, 289 at an interface between the process chamber and the lid 215. In some embodiments, a thermal gasket (not shown) may be disposed beneath the valve 100 and the process chamber. In some embodiments, the thermal gasket may be formed of a material capable of withstanding temperatures between about 65° C. and about 80° C. such as, for example, a ceramic, polytetrafluoroethylene, or VESPEL®.

The lid 215 is pivotably coupled to the processing chamber using a hinge (not shown). The lid 215 allows for convenient access to the chamber components such as the chamber liners 255 for example, for cleaning. In some embodiments, a cover 261 may be disposed on the lid 215 to protect components disposed the lid 215. When the lid 215 is in a closed position (as shown in FIG. 2), the lid 215 exerts a force on the shaft 110 opposite to and greater than the biasing force exerted by the biasing element 116. Thus, process gas is allowed to flow through from the gas source 288, through gas feedthroughs 287, 289, through the valves 100, and into the gas distribution assembly 216. When the lid 215 is in an open position (as shown in FIG. 3), the lid 215 does not contact the shaft 110 and the biasing element 116 forces the flange 112 against the upper wall 115 of the lower portion 105 of the valve 100, thus advantageously sealing off the gas feedthroughs 287, 289 from the ambient environment. As a result, ambient air does not interact with process gases still in the gas feedthroughs 287, 289 after processing, thus preventing deposits on the walls of the gas feedthroughs 287, 289.

As illustrated in FIGS. 2 and 3, to help decrease chamber servicing (i.e., cleaning) time, a removable chamber liner 255 may be disposed adjacent the sidewalls 205A,B and interior wall 206. The chamber liners 255 include an aperture 262 formed in the chamber liners 255 and in communication with the aperture 209. The apertures 262 and 209 are positioned as such to enable substrates to be moved into and out of the respective process chambers 200, 201. As such, each of the apertures 209, 262 may generally be in selective communication with, for example, a substrate transfer chamber (not shown). During servicing, the lid 215 is left open so that the interior of the process chambers 200, 201 may be accessed.

When the substrate supports 208 are in a processing position, the upper portion 219 of the respective first and second tandem process chambers 200, 201 and substrate supports 208 generally define the respective isolated processing regions 202, 203 to provide process isolation between each of the respective process chambers 200, 201. Therefore, in combination, the sidewalls 205A,B, interior wall 206, substrate support 208, and the lid 215 provide process isolation between the processing regions 202, 203.

The volume of the processing regions 202, 203 and loading regions 211 may vary with the position of the substrate support 208 relative to the lower boundary of the lid 215. In one configuration, the substrate supports 208 may be lowered below the apertures 209. In the lowered position, a substrate may be positioned on the substrate support 208 via the aperture 209. More particularly, when the substrate support 208 is lowered, the lift pin assembly 212 may lift a substrate from the upper surface of the substrate support 208. Subsequently, a robot blade (not shown) may enter into the loading region 211 and engage the substrate lifted by the lift pin assembly 212 for removal from the loading region 211. Similarly, with the substrate support 208 in a lowered positioned, substrates may be placed on the substrate support 208 for processing. Subsequently, the substrate support 208 may be vertically moved into a processing position, i.e., a position where the upper surface of the substrate support 208 is positioned proximate to the respective processing region 202, 203.

The lid 215 may have other plasma generation devices disposed adjacent to the lids 215. The upper electrode assembly 218 may be configured with RF coils coupled to first and second RF sources 250, 252 through respective matching networks 251, 253, to inductively couple RF energy into the plasma processing regions 202, 203. An RF power supply controller 249 may be coupled to both RF power sources 250, 252 to provide an output signal for controlling, for example, a power level, phase control, and/or frequency.

The lower portion 231 of the respective first and second tandem process chambers 200, 201 may also include a commonly shared adjacent chamber region of each chamber defined by a central pumping plenum 217, wherein the central pumping plenum 217 is in fluid communication with a vacuum source 220 through a pumping valve 221. Generally, the central pumping plenum 217 includes two sections defined by the sidewalls 205A,B that are combined with an output port 230 in fluid communication with the pumping valve 221. The two sections may be formed as part of the lower portion 231 of each first and second tandem process chambers 200, 201. While the central pumping plenum 217 may be formed integral to the lower portion 231 of the first and second tandem process chambers 200, 201, the central pumping plenum 217 may alternatively be a separate body coupled to the lower portion 231. In a gas purge or vacuum process, the pumping valve 221 couples the vacuum source 220 to the output port 230 through mounting flange 214. Therefore, the central pumping plenum 217 is generally configured to maintain the respective process chambers 200, 201, and more particularly, the respective processing regions 202, 203, at a pressure desired for semiconductor processing while allowing for rapid removal of waste gases using the vacuum source 220.

In some embodiments, the output port 230 is positioned at a distance from the processing regions 202, 203 such as to minimize RF energy in the processing regions 202, 203, thus minimizing striking a plasma in the exhaust gases being flushed from the process chambers 200, 201. For example, the output port 230 may be positioned at a distance from the substrate supports 208 and processing regions 202, 203 that is sufficiently far to minimize RF energy within the output port 230.

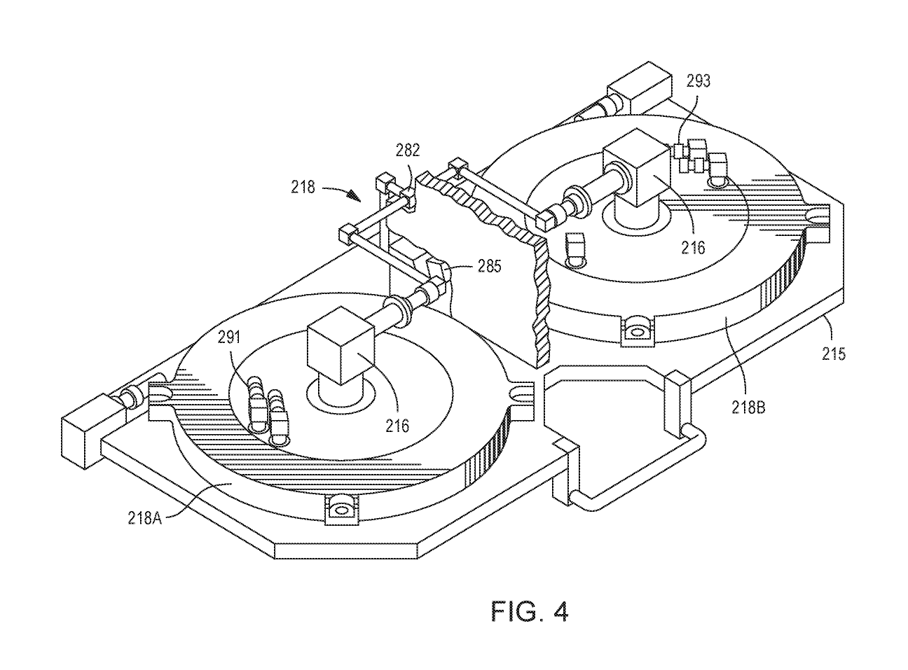

FIG. 4 is a perspective view of the lid 215 including an upper electrode assembly 218. The lid 215 and/or first and second tandem process chambers 200, 201 may include cooling passages (not shown) that circulate coolant received from an upper coolant input/output port 285. In some embodiments, the upper electrode assembly 218 includes a first upper electrode assembly 218A and a second electrode assembly 218B disposed adjacent the processing regions and adapted to provide RF energy to respective processing regions 202, 203 (See FIGS. 2 and 3). To provide thermal control to the upper electrode assembly 218, cooling channels 294 for the first and second upper electrode assemblies 218A and 218B may be coupled to an external coolant source (not shown) by a first and second coolant input 291 and 293, respectively. In some embodiments, a gas splitter assembly 282 may be used to couple process gas source 288 to the gas distribution assembly 216.

Although the previous description has been made with regards to a tandem process chamber, the valve 100 may be utilized in any process chamber in which sealing of a gas line is desirable. The valve 100 may further be utilized in any scenario in which the sealing of a gas line is desirable.

While the foregoing is directed to some embodiments of the present disclosure, other and further embodiments may be devised without departing from the basic scope of the disclosure.

What is claimed is:

1. A valve, comprising:
a valve body having an upper portion and a lower portion, wherein the upper portion includes a central opening and is configured to interface with a gas line, and wherein the lower portion includes an inner volume;
a coupling member disposed within the inner volume and having a central conduit configured to be coupled to a gas feedthrough, wherein the inner volume is defined by an upper surface of the coupling member and an upper wall and sidewalls of the lower portion;
a sealing member having a shaft extending through the central opening and a flange extending radially outward from the shaft in the inner volume, wherein the flange includes an upper surface which opposes the upper wall of the lower portion; and
a biasing element disposed between the sealing member and the coupling member to bias the sealing member against the upper wall to seal off the inner volume.

2. The valve of claim 1, wherein the shaft protrudes beyond an upper surface of the upper portion.

3. The valve of claim 2, wherein the shaft protrudes beyond the upper surface of the upper portion by about 2.5 millimeters.

4. The valve of claim 1, wherein the sealing member is moveable between a first position, in which the sealing member seals off the inner volume, and a second position, in which the inner volume is fluidly coupled to the central opening.

5. The valve of claim 4, wherein, in the first position, an upper surface of the flange abuts the upper wall of the lower portion, and wherein, in the second position, a spacing between a lower surface of the flange and the upper surface of the coupling member is about 5 millimeters.

6. The valve of claim 1, wherein the sealing member is formed of a polymer. The valve of claim 1, wherein the sealing member is formed of aluminum.

8. The valve of claim 1, wherein the biasing element is a helical spring.

9. The valve of claim 8, further comprising:
a first annular groove formed in the upper surface of the coupling member; and
a second annular groove formed in a lower surface of the flange of the sealing member, wherein a first end of the helical spring is disposed in in the first annular groove and a second send of the helical spring is disposed in the second annular groove.

10. A processing chamber, comprising:
a chamber body defining a processing region within;
a lid pivotably coupled to the chamber body to close off the processing region;
a gas feedthrough extending through the chamber body to provide a process gas to the lid, wherein the gas feedthrough includes a valve disposed at an interface between the gas feedthrough the lid, the valve comprising:
a valve body having an upper portion and a lower portion, wherein the upper portion includes a central opening and is configured to interface with a gas line, and wherein the lower portion includes an inner volume;
a coupling member disposed within the inner volume and having a central conduit configured to be coupled to the gas feedthrough;
a selectively moveable sealing member having a shaft extending through the central opening and a flange extending radially outward from the shaft in the inner volume; and
a biasing element disposed between the sealing member and the coupling member to bias the sealing member against an upper wall of the lower portion to seal off the inner volume.

11. The processing chamber of claim 10, wherein the lid is moveable between a closed position and an open position, and wherein, in the closed position, the lid exerts a force against the shaft greater than a biasing force of the biasing element, and wherein, in the open position, the lid is not in contact with the shaft and the sealing member abuts the upper wall of the lower portion to seal off the inner volume.

12. The processing chamber of claim 11, wherein the lid includes a gas distribution assembly including a showerhead configured to dispense a gas to the processing region, and wherein the gas distribution assembly is fluidly coupled to the gas feedthrough when the lid is in the closed position.

13. The valve of claim 10, wherein the shaft protrudes beyond an upper surface of the upper portion.

14. The valve of claim 13, wherein the shaft protrudes beyond the upper surface of the upper portion by about 2.5 millimeters.

15. The valve of claim 10, wherein the sealing member is moveable between a first position, in which the sealing member seals off the inner volume, and a second position, in which the inner volume is fluidly coupled to the central opening.

16. The valve of claim 15, wherein, in the first position, an upper surface of the flange abuts the upper wall of the lower portion, and wherein, in the second position, a spacing between a lower surface of the flange and the upper surface of the coupling member is about 5 millimeters.

17. The valve of claim 10, wherein the sealing member is formed of a polymer.

18. The valve of claim 10, wherein the sealing member is formed of aluminum.

19. The valve of claim 10, wherein the biasing element is a helical spring.

20. A valve, comprising:
a valve body having an upper portion and a lower portion, wherein the upper portion includes a central opening and is configured to interface with a gas line, and wherein the lower portion includes an inner volume;
a coupling member disposed within the inner volume and having a central conduit configured to be coupled to a gas feedthrough, wherein the inner volume is defined by an upper surface of the coupling member and an upper wall and sidewalls of the lower portion, wherein the upper surface includes a first annular groove;
a sealing member having a shaft extending through the central opening and a flange extending radially outward from the shaft in the inner volume, wherein the flange includes an upper surface which opposes the upper wall of the lower portion, wherein a lower surface of the sealing member includes a second annular groove; and
a helical spring disposed between the sealing member and the coupling member to bias the sealing member against the upper wall to seal off the inner volume, wherein a first end of the helical spring is disposed in in the first annular groove and a second send of the helical spring is disposed in the second annular groove.
